(19) United States
(12) Patent Application Publication
(10) Pub. No.: US 2001/0055276 A1
(43) Pub. Date: Dec. 27, 2001

(54) Apparatus for adjusting a local sampling rate based on the rate of reception of packets

(76) Inventors: Shane M. Rogers, Calgary (CA); Tim Kuechler, Calgary (CA)

Correspondence Address: NORTEL NETWORKS LIMITED, Intellectual Property Law Group, Station "C", P.O. Box 3511, Ottawa, ON, K1Y 4H7, CA

(21) Appl. No.: 09/797,674

(22) Filed: Mar. 5, 2001

(30) Foreign Application Priority Data
Mar. 3, 2000 (CA) 2,299,943

(51) Int. Cl. G01R 31/08; G06F 11/00; G08C 15/00; H04J 1/16; H04J 3/14

(52) U.S. Cl. 370/232

(57) ABSTRACT

A packet network interface for delivering streaming data to an analog output is described which can compensate for a sampling rate mismatch between the far-end transmitter and the local receiver by monitoring the rate of reception of packets and adjusting the local (receive) sampling rate responsive to said rate of reception. Typically, the rate of reception of packets is monitored by monitoring the level of a jitter buffer used to compensate for variable delays in the rate of reception. If the average level is too high or two low, this is a likely indication that there is a rate mismatch between the far end and local sampling rate. Adjustments are then made to the local sampling rate to adjust for such a mismatch.

### FIELD OF THE INVENTION

The present invention relates to data transmission of streaming data. The invention is particularly suited for voice over packet data networks, for example Voice over Internet Protocol (VOIP) networks.

### BACKGROUND OF THE INVENTION

For packet networks, audio signals are digitized into samples and transmitted as packets. These packets can include one or more samples. The transmitter sends these packets at a constant transmission rate. An appropriately configured receiver will receive the packets, extract the samples of digital data and convert the digital data into analog output using a digital to analog (D/A) converter. One of the characteristics of a packet network is that packets will not necessarily arrive at their destination at a constant rate, due to variable delays through the network. However, digital audio data (for example a digitized voice conversation) must be played out at a constant output rate in order to reconstruct the audio signal, and the D/A converter operates at such a constant output rate (the OUTPUT sampling rate).

A known solution for this problem is to implement a jitter buffer in the receiver. A jitter buffer stores samples as they are received from the network. After several samples are loaded into the buffer, the samples in the buffer are output at the constant output rate. As long as the average rate of reception of the packets is equal to the constant output rate, the jitter buffer allows the packets to be output at the constant output rate even though they are not necessarily received at a constant rate.

In traditional (e.g., PSTN) digital telephony systems, end points are synchronized by a common master clock in order to ensure that the D/A and A/D converters at both ends operate at the same sampling rate. In other words, the PSTN is a synchronous network, and thus the constant transmission rate is the same as the constant output rate. However in a packet based system, there is no common clock to ensure synchronization of the data rates. Thus the two endpoints will typically have marginally different data rates. Thus the constant output rate from the jitter buffer will differ from the far-end constant transmission rate.

For example, let us assume that the clock (sampling) rate of the A/D converter of the far-end transmitter is slightly faster than the clock (sampling) rate of the D/A converter of the receiver. This will result in the far end transmitter sending digital samples of audio data at a rate faster then the local receiver will be converting the digital samples into analog. This will result in an output rate of the jitter buffer that is slower than the far-end transmission rate. Eventually this could result in the jitter buffer becoming full. In traditional jitter buffer designs, this will result in a random discard of a sample, which degrades audio quality. If the rate mismatch between the far end transmitter and the local receiver is such that the far end sampling rate is slightly less than the sampling rate of the local D/A converter, then the output rate from the jitter buffer is less than the far end transmission rate. Eventually this could result in the jitter buffer becoming empty and will therefore no longer be able to compensate for random delays in the network. In traditional jitter buffer designs this condition will result in the previous sample being repeated until the next packet arrives which degrades the audio quality.

Thus, while known jitter buffer techniques can compensate for variable transmission delays through the network (provided the average rate of reception is equal to the constant output rate), the jitter buffer can be either depleted or filled to capacity due to a rate mismatch between the far-end transmitter and the local receiver.

There exists a need to overcome this problem.

### SUMMARY OF THE INVENTION

It is an object of the invention to overcome this problem by monitoring the rate of reception of packets and adjusting the local (receive) sampling rate responsive to said rate of reception. In a preferred embodiment, the rate of reception of packets is monitored by monitoring the level of a jitter buffer used to compensate for variable delays in the rate of reception. If the average level is too high or two low, this is a likely indication that there is a rate mismatch between the far end and local sampling rate. Adjustments are then made to the local sampling rate to adjust for such a mismatch.

According to one aspect of the invention there is provided apparatus comprising: a packet interface for receiving packets from a variable delay packet network; and a controller for monitoring the reception rate of said packets and for sending control signals to a sample rate generator for adjusting the sampling rate used to process samples of digital data. Preferably the rate of reception is compared against at least one threshold to determine whether the sampling rate should be adjusted. Preferably both a first and second threshold is used, with adjustments in both directions.

According to another aspect of the invention there is provided apparatus for receiving streaming data from a variable delay packet network comprising:

A packet interface for receiving packets from a variable delay packet network;

A digital-to-analog converter for converting samples of streaming data into analog signals;

A sampling rate generator for producing a sampling signal for controlling the sampling rate of said digital-to-analog converter, said sampling rate generator including a control input for receiving a control signal to adjust the sampling signal; and

A controller for monitoring the rate of reception of said packets and for sending control signals to said sampling rate generator for adjusting the sampling rate used to process said packets responsive to said rate of reception.

According to another aspect of the invention there is provided an article including one or more machine-readable storage media containing instructions for processing streaming packets in a packet-based network, the instructions when executed causing a device to: receive packets from a packet based network; monitor the reception rate of said packets; compare said reception rate against at least one threshold; send signals to a sampling rate generator for adjusting the sampling rate used to convert said samples into analog signals based on said reception rate. Typically these instructions will be software instructions for a device controller, which may be a microprocessor, Digital Signal Processor, or some combination thereof.

Another broad aspect of the invention can take the form of a data signal embodied in a carrier wave and including code segments containing instructions for processing streaming packets in a packet-b;based network, the instructions when executed causing a device to:

receive packets from a packet based network;

monitor the reception rate of said packets;

compare said reception rate against at least one threshold;

send signals to a sampling rate generator for adjusting the sampling rate used to convert said samples into analog signals based on said reception rate.

Another broad aspect of the invention can take the form of a method for processing streaming packets in a packet-based network comprising the steps of:

receiving packets from a packet based network;

monitoring the reception rate of said packets;

comparing said reception rate against at least one threshold; and

responsive to said comparing step, sending signals to a sampling rate generator for adjusting the sampling rate used to convert said samples into analog.

### BRIEF DESCRIPTION OF THE DRAWINGS

The present invention, together with further objects and advantages thereof will be further understood from the following description of the preferred embodiments with reference to the drawings in which:

FIG. 1 illustrates a VoIP apparatus connected to an IP network according to an embodiment of the invention.

FIG. 2 is a functional block diagram of the controller of the VoIP apparatus according to an embodiment of the invention.

FIG. 3 is a Hardware block diagram illustrating the VoIP apparatus according to an embodiment of the invention.

FIG. 4 is a flowchart illustrating the method steps carried out in a processor of the VoIP apparatus according to an embodiment of the invention.

### DETAILED DESCRIPTION OF THE PREFERRED EMBODIMENTS

We will describe the preferred embodiments of the invention with reference to the example of a Voice over IP (VOIP) apparatus and a telephone call (e.g., a voice conversation). However, the invention is also applicable to other types of streaming data (e.g., audio or video) that must be delivered at a constant rate. Furthermore, the invention is not limited to IP, and can be used with other packet data networks. Furthermore, for convenience, we will discuss the examples of a VoIP apparatus which forms part of, or connects to a single voice terminal. However, it should be noted that the invention can be implemented in a network device, for example a PSTN-IP gateway, or PBX or Key system.

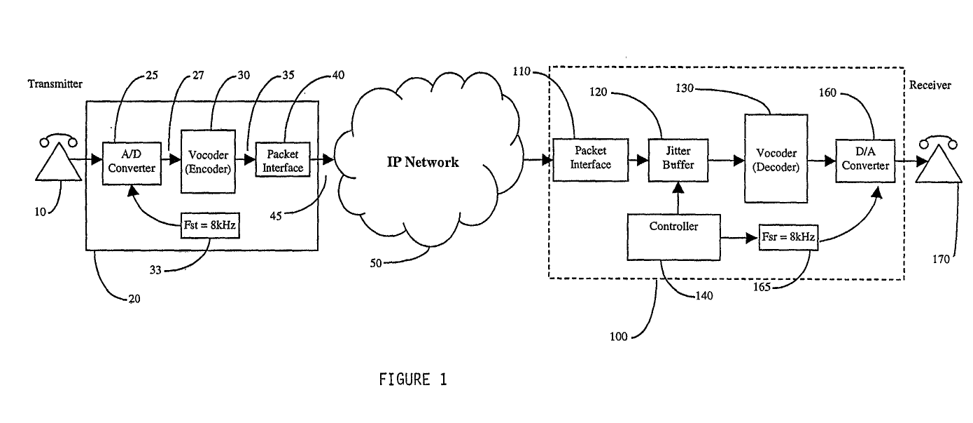

FIG. 1 illustrates a voice over IP apparatus connected to an IP network according to an embodiment of the invention. In FIG. 1, an IP network 50 provides transmission of voice packets from a far-end transmitter 20 to a local receiver 100. In this particular example, the far-end transmitter includes a handset 10 and a voice over IP (VoIP) transmitter 20. In this example, the voice over IP transmitter 20 includes an analog to digital (A/D) converter 25, for example, a CODEC. The A/D converter 25 digitizes audio from the handset 10 at a constant transmission rate which depends on a transmit sampling rate provided by a “transmit” sample rate generator 33. The output from the A/D converter 25, for example, aL PCM (Pulse Code Modulated) signal 27 is sent to a vocoder that processes the samples of digital/audio data according to a particular vocoding algorithm in use. The processed samples 35 are sent to an IP packet interface 40 which structures the samples into IP packets 45 according to known Internet protocols and then sends these packets to the IP network 50 for transmission to the receiver. The packets 45 are sent at a constant transmission rate that is dictated by the A/D converter 25 and its transmit sampling rate provided by the “transmit” sample rate generator 33.

Note that packets can include multiple samples (or frames) of audio data depending on the vocoding standards used. For simplicity we will discuss a generic example and refer to packets as what is transported on the packet network. Furthermore, as there is a relationship between packets and samples, we will discuss the preferred embodiment using a simplified example wherein each packet contains a single sample. The techniques described can readily be extended to protocols for which IP packets include multiple samples or frames.

The IP network adds a variable delay such that the receiver does not necessarily receive the packets at the same rate as they were transmitted. The receiver VoIP apparatus 100 comprises an IP packet interface 110, which receives the IP packets from the IP network 50. These packets are then stored temporarily in a jitter buffer 120, which is controlled by a jitter buffer manager 140. The packets are then sent to a vocoder 130 that deconstructs the samples according to a particular vocoder routine. The vocoder 130 produces, for example, PCM output, which is sent to the D/A converter 160 (e.g., a CODEC), which converts the digital signal into an analog audio signal that is sent to the handset 170. The constant output rate of the receiver 100 is dictated by the “receive” sampling rate provided by a “receive” sample rate generator 165 that controls the “sampling” or “playback” rate of the CODEC.

As stated previously in the background section, conventional jitter buffers can typically compensate (or at least alleviate) random delays of packet transmission through the IP network 50. However, conventional jitter buffers fail to compensate for a rate mismatch between the transmit sampling rate provided by the transmit sample rate generator 33 in the far-end transmitter and the receive sampling rate provided by the receive sample rate generator 165 in the local receiver. This rate mismatch results in a constant transmission rate that differs from the constant output rate. This will tend to either deplete or fill the jitter buffer. This typically results in previous samples being repeated in the case where the jitter buffer is empty, or the random discard of samples in the case of a fill jitter buffer. Either way, the audio quality is degraded.

The VoIP apparatus compensates for such a rate mismatch by adjusting the “receive” sampling rate generated by the sample rate generator 165.

Note that the VoIP apparatus can take a variety of forms. In one form, the voice over IP apparatus forms part of an integrated phone, which includes the VoIP apparatus, an optional screen display, a keypad and a handset. Alternatively, the VoIP apparatus can form part of a key system or PBX and include an interface for allowing a digital phone (for example, a phone adapted to work with a digital key system or digital PBX) to communicate via a packet network by coupling to the VoIP apparatus. In this example, the D/A converter will be located in the digital phone, and the phone will derive its sampling rate by phase locking to an output sampling signal provided by the VoIP apparatus (as is known in the PBX art). Furthermore, the VoIP apparatus can include a subscriber line interface circuit (SLIC) for coupling to a conventional analog phone. Furthermore, note that the transmitter 20 can form part of a PSTN-IP Gateway, as can the VoIP apparatus 100.

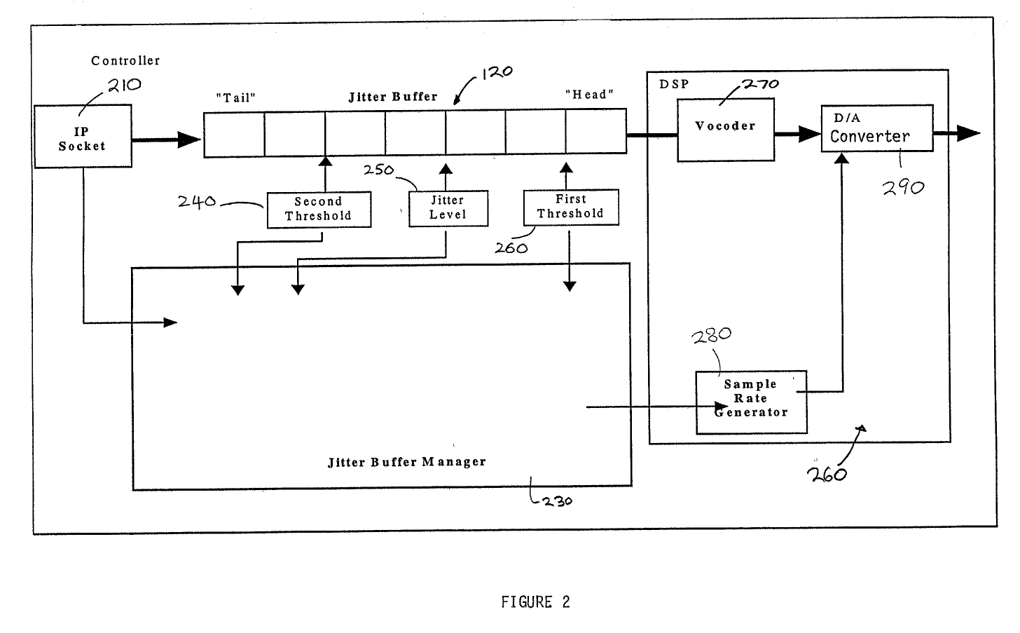

FIG. 2 is a functional block diagram of the controller of the VoIP apparatus according to an embodiment of the invention. FIG. 2 includes functional blocks representing an IP socket 210, a jitter buffer 120, a jitter buffer manager 230 and an audio processing DSP 260. The jitter buffer manager will typically be implemented as software instructions executed on a controller, for example, a microprocessor or an advanced RISC machine (ARM) and associated memory. In the embodiment shown, the DSP 260 includes a vocoder 270, a Digital-to-Analog (D/A) Converter 290 and a Sample Rate Generator 280.

The jitter buffer is a variable length buffer usually on the order of a few tens of milliseconds long. The jitter buffer should be long enough to be able to store a sufficient number of packets such that the jitter buffer manager can accommodate the first threshold, as explained below, while still allowing for some headroom for short packet bursts, over the entire range of expected desired jitter buffer depths. The jitter buffer length is also constrained by cost and performance factors and the desired jitter level. The desired jitter level represents a trade-off between added delay, which is generally undesirable, and the need to compensate for large variations in packet reception rates as well as packets received in a non-sequential order.

In FIG. 2, an IP socket 210 (which is an application programming interface (API)) is used to gain access to the IP network through the packet interface 110 of FIG. 1 and deliver IP packets to the jitter buffer manager 230. As is known in the art, packets can include more than one sample of digital data. The Jitter Buffer Manager sequences and stores the incoming packets in the Jitter Buffer in a conventional manner. Note that the rate of reception of the packets is thus related to the rate packets are inserted into the jitter buffer. Thus the controller can monitor the rate of reception of the packets by monitoring the level or depth of the jitter buffer.

The Jitter Buffer Manager manages the Jitter Buffer to compensate for variable delays in the network in a conventional manner (e.g., inserts or deletes packets as required for underflow/overflow situations). In addition, in this embodiment of the invention, there is associated with the jitter buffer 120, a first threshold 240, a desired optimum jitter level 250, and a second threshold 260. Both the first threshold and the second threshold represent buffer conditions used by the controller to evaluate whether the reception rate of packets requires an adjustment to the sampling rate. If the jitter buffer level expands to exceed the first threshold, this indicates a condition that may result in jitter in arrival rate of the received packets propagating through the jitter buffer to the vocoder and affecting the audio quality of the signal. This is likely to result from a rate mismatch such that the local (receiver) sampling rate is slower than the far-end (transmitting) sampling rate. Thus, for example, if the Jitter Buffer is more that ¾ full (assuming a first threshold of ¾), the controller increases the local sampling rate to compensate for the mismatch.

If the jitter buffer depth drops below the second threshold, this signals that the total delay of the jitter buffer is getting too long and this can also negatively affect the perceived audio quality. This is likely to result from a rate mismatch such that the local (receiver) sampling rate is faster than the far-end (transmitting) sampling rate. Thus, for example, if the Jitter Buffer is less than ¼ full (assuming a second threshold of ¼), the controller decreases the local sampling rate to compensate for the mismatch.

For the case where the optimum jitter buffer level is being dynamically adjusted in response to network performance, the controller will also scale said first and second thresholds in the same manner.

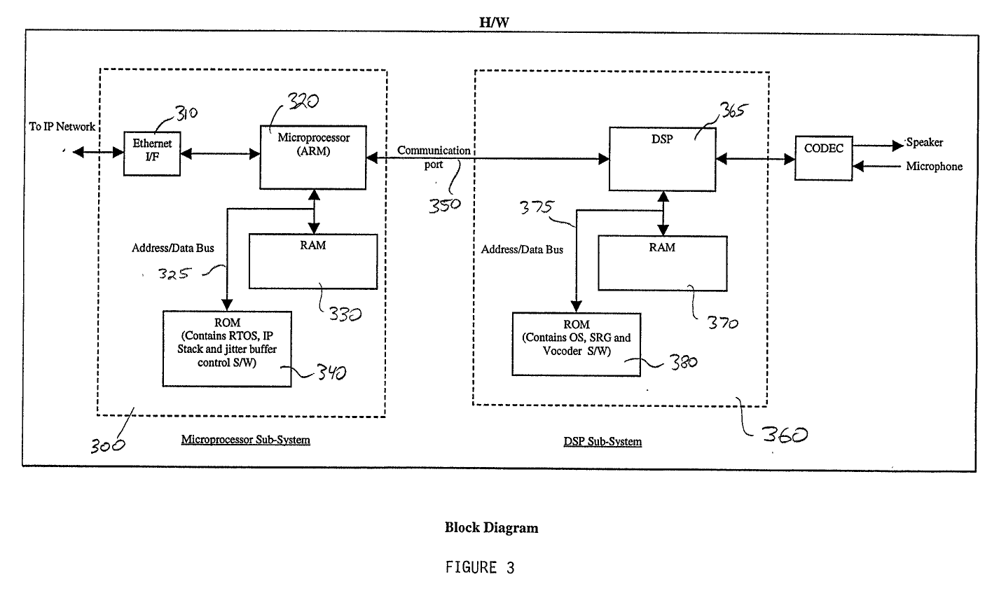

FIG. 3 is a hardware block diagram illustrating the hardware components of a VoIP apparatus according to an embodiment of the invention for implementing the functional blocks of FIG. 2. According to this embodiment, the hardware includes a microprocessor subsystem 300 and a Digital Signal Processor (DSP) subsystem 360. The microprocessor subsystem and the DSP subsystem are interconnected via communication port 350. The microprocessor subsystem 300 includes a microprocessor 320, for example, an Advanced Risk Machine (ARM) processor 320, RAM 330, an address/data bus 325 and ROM 340, as well as an Ethernet interface 310. Note that the RAM represents working memory for implementing the jitter buffer and storing the values of variables whereas the ROM contains the real-time operating system (RTOS), the IP stack and the jitter buffer control software. Similarly, the DSP subsystem includes a DSP 365, RAM 370 and ROM 380 for containing software instructions for implementing, for example, the OS (the Operating System), the sample rate generator and the vocoder software. The DSP subsystem also includes an address/data bus 375. The microprocessor 320 and the DSP 365 communicate via communication port 350, which allows the transmission of both samples and signaling between the two subsystems. The DSP is also connected to a CODEC 160 for producing analog output to the receiver speaker on the receive side and also for receiving analog input from the microphone of the receiver. The Codec can of course form part of the DSP in equivalent structures. Note that this drawing only illustrates the components required to implement the functions of FIG. 2 and other components for implementing a fully functional device will also be required, as should be apparent to a person skilled in the art. For example, the device can include a screen, keypad, and echo controller (which can include a switched loss system) for switching between receive mode, quiescent mode and transmit mode. Furthermore, we will collectively refer to the microprocessor subsystem 300 and the DSP subsystem as a controller.

In this embodiment, the microprocessor subsystem 300 implements the jitter buffer, the IP stack (accessed through the IP socket), and the jitter buffer manager. The DSP subsystem 360 implements the vocoder and sample rate generator according to this embodiment of the invention. However, it should be apparent to a person skilled in the art that many different alternative implementations could be used, for example entire functionality could be implemented in one processor or individual pieces could be implemented in hardware (e.g. ASIC).

In the embodiment shown in FIG. 2 and 3, the sampling rate generator is part of the audio processing DSP for example the TMS320C54x family of DSPs manufactured by Texas Instruments Inc.. The DSP uses an adjustable rate timer to produce the sampling rate signal used by the D/A (Codec). The sampling rate can be adjusted by the microprocessor by sending a control signal to the audio processing DSP as is known in the art. Of course using a separate sample rate generator (for example an oscillator (which may be tunable) and a clock divider for controlling the sampling rate) would be an alternative equivalent.

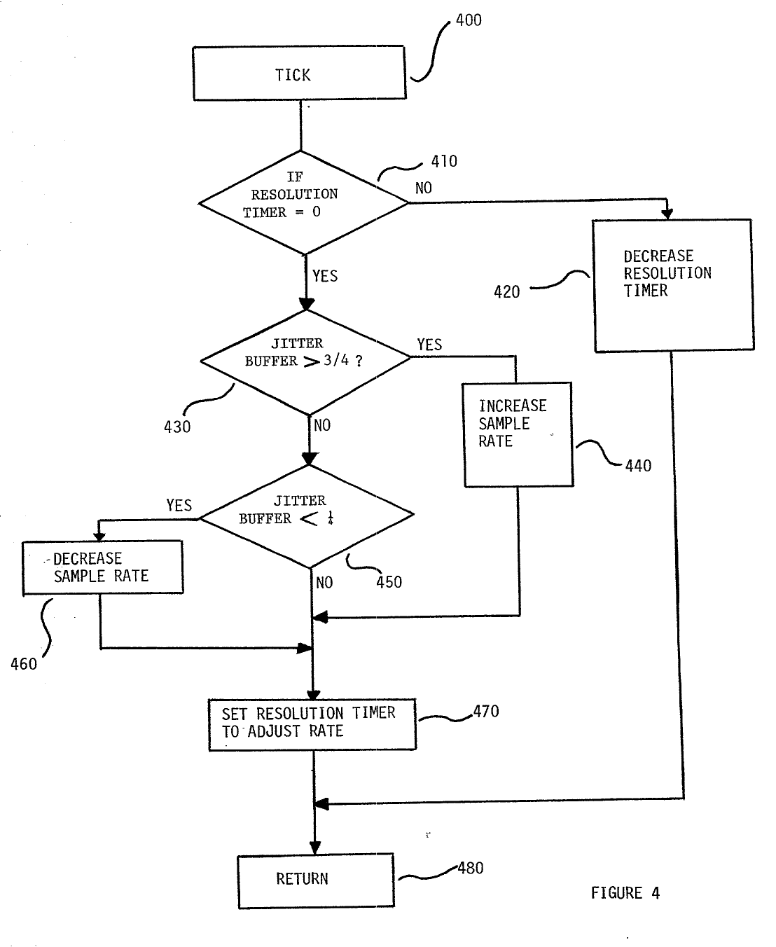

We will now discuss the method steps carried out by a processor of the VoIP apparatus according to an embodiment of the invention. For example, software instructions for carrying out these steps can be executed by the microprocessor, DSP or both, depending on the implementation. FIG. 4 is a flowchart illustrating the steps carried out by an embodiment that is time based (e.g., uses DSP operating cycles) to determine how often the rate of reception of packets should be used to adjust the sampling rate. In FIG. 4, for each DSP operating interval “tick”400, the DSP determines if sufficient time has passed by evaluating whether a resolution timer has reached zero 410. If not, the DSP decreases the resolution timer 420 and waits for the next tick. If the resolution timer has reached zero, the DSP checks if the jitter buffer manager is at a level that requires adjustment to the sample rate (i.e.: the jitter buffer depth is either above the first threshold or below the second threshold). If this condition is true, then the DSP adjusts the sample rate accordingly. As an example if the jitter buffer controller indicates that the jitter buffer level has exceeded a first threshold (e.g., ¾), the DSP will increase the sampling rate 440 of the sample rate generator. If however the jitter buffer controller indicates that the jitter buffer level is below a second threshold (e.g., ¼), the DSP decreases the sampling rate 440 of the sample rate generator. Finally, the resolution timer is reset to an adjust rate 470 and the system waits for the next tick. Preferably the adjust rate is itself adjustable. For example, if the DSP is required to adjust the sample rate in the same direction in N consecutive periods of the adjust rate, this indicates a condition where it is preferable to increase the adjust rate to allow the adjustments to be implemented faster. N is chosen for the predicted network conditions.

Note that FIG. 4 illustrates a timer based process wherein the DSP operating cycles are used to determine how often reception rate should be evaluated in order to determine whether the sampling rate should be adjusted. Of course the process can be more event driven, for example, based on the arrival of a packet, in which case the entire process can be implemented in the microprocessor 300. For example, comparing steps 430/450 are executed after a number of packets have been received since the previous comparing step is executed, wherein said number is one or more.

Numerous modifications, variations and adaptations may be made to the particular embodiments of the invention described above without departing from the scope of the invention, which is defined in the claims.

What is claimed is:

1. Apparatus comprising:
a packet interface for receiving packets from a variable delay packet network; and
a controller for monitoring the reception rate of said packets and for sending control signals to a sample rate generator for adjusting the sampling rate used to process samples of digital data.

2. Apparatus as claimed in claim 1 wherein said controller adjusts said sampling rate by monitoring said reception rate and responsive to said reception rate exceeding a first threshold said controller sends a control signal to said sample rate generator for increasing said sampling rate and responsive to said reception rate being below a second threshold said controller sends a control signal to said sample rate generator for decreasing said sampling rate.

3. Apparatus as claimed in claim 2 wherein said first and second thresholds are updated dynamically by said controller responsive to network performance.

4. Apparatus as claimed in claim 3 further comprising a jitter buffer for storing samples of streaming data carried in received packets, and said controller executes buffer management instructions for controlling said jitter buffer wherein said controller monitors said reception rate by determining the number of samples stored in said jitter buffer and compares said number to said first and second thresholds.

5. Apparatus for receiving streaming data from a variable delay packet network comprising:
A packet interface for receiving packets from a variable delay packet network;
A digital-to-analog converter for converting samples of streaming data into analog signals;
A sampling rate generator for producing a sampling signal for controlling the sampling rate of said digital-to-analog converter, said sampling rate generator including a control input for receiving a control signal to adjust the sampling signal; and
A controller for monitoring the rate of reception of said packets and for sending control signals to said sampling rate generator for adjusting the sampling rate used to process said packets responsive to said rate of reception.

6. Apparatus as claimed in claim 5 wherein said controller compares said rate of reception against a first threshold and a second threshold and wherein said controller sends a control signal to said sampling rate generator to increase the sampling rate when said rate of reception exceeds said first threshold and wherein said controller sends a control signal to said sampling rate generator to decrease the sampling rate when said rate of reception is less than said second threshold.

7. Apparatus as claimed in claim 6 wherein said apparatus further comprises a jitter buffer for storing packets received by said packet interface and wherein said controller monitors the rate of reception by determining the number of packets stored in said jitter buffer.

8. The apparatus as claimed in claim 7 wherein said controller updates said first and second thresholds dynamically responsive to network performance.

9. The apparatus as claimed in claim 7 further comprising an audio processing Digital Signal Processor (DSP) which includes said sampling rate generator, said DSP operating at a timing cycle and wherein said controller compares said rate of reception at regular intervals based on an adjust rate which depends on said timing cycle.

10. An article including one or more machine-readable storage media containing instructions for processing streaming packets in a packet-based network, the instructions when executed causing a device to:
receive packets from a packet based network;
monitor the reception rate of said packets;
compare said reception rate against at least one threshold;
send signals to a sampling rate generator for adjusting the sampling rate used to convert said samples into analog signals based on said reception rate.

11. A data signal embodied in a carrier wave and including code segments containing instructions for processing streaming packets in a packet-based network, the instructions when executed causing a device to:
receive packets from a packet based network;
monitor the reception rate of said packets;
compare said reception rate against at least one threshold;
send signals to a sampling rate generator for adjusting the sampling rate used to convert said samples into analog signals based on said reception rate.

12. A method for processing streaming packets in a packet-based network comprising the steps of:
receiving packets from a packet based network;
monitoring the reception rate of said packets;
comparing said reception rate against at least one threshold; and
responsive to said comparing step, sending signals to a sampling rate generator for adjusting the sampling rate used to convert said samples into analog.

13. The method as claimed in claim 12 wherein said comparing step is executed after a number of packets have been received since the previous comparing step is executed.

14. The method as claimed in claim 13 wherein said number is one.

15. The method as claimed in claim 12 wherein said comparing step is executed after a duration of time expires since the previous comparing step is executed.

16. The method as claimed in claim 15 wherein said duration of time depends on a timer associated with a digital signal processor used in a device which carries out said method.
